(19) United States
(12) Patent Application Publication
(10) Pub. No.: US 2001/0055729 A1
(43) Pub. Date: Dec. 27, 2001

(54) Method for decorating an item and item decorated using the method

(76) Inventors: Alain Bethune, Savigny (FR); Sophie Helene Vayrette, Courbevoie (FR)

Correspondence Address: Thomas L. Irving, FINNEGAN, HENDERSON, FARABOW,, GARRETT & DUNNER, LLP, 1300 I Street, N.W., Washington, DC, 20005-3315, US

(21) Appl. No.: 09/824,213

(22) Filed: Apr. 3, 2001

(30) Foreign Application Priority Data
Apr. 3, 2000 (FR) 00 04214

(51) Int. Cl. G03C 1/492; G03C 1/494; G03C 1/76; G03F 7/00

(52) U.S. Cl. 430/275.1; 430/310; 430/945

(57) ABSTRACT

A method for producing at least one decorative pattern on an item includes providing a support having at least one surface and treating a first portion of the surface of the support. The treatment renders the first portion of the surface resistant to metallic coating by at least one type of metallic coating procedure. In addition, the method includes coating a second portion of the surface of the support with a metallic coating such that the metallic coating delimits a decorative pattern. The first portion of the surface corresponds to the decorative pattern.

The present invention relates to a method for producing at least one decoration on an item, for example, a stopper as commonly used on containers for perfumes or other cosmetic products. The invention also relates to an item decorated using this method. The decoration may include, for example, a logo, a brand mark, a design, or any other inscription or distinctive sign.

In the field of cosmetics, for example, the packaging of perfumes or scents, use is made of decorated stoppers, for example, stoppers with a gold or chrome finish on their entire outer surface or on just part of it, so as to reveal a decoration or a design.

One of the techniques used to achieve such a decoration or design includes metallizing the plastic part and protecting those parts which are not to be metallized with, in particular, a varnish. However, the surface on which the varnish is placed is not treated. Instead, that part of the surface is merely covered. The varnish is then possibly removed.

According to another manufacturing technique, the plastic part that is to be metallized is obtained by molding two plastics compatible with one another, one of them being metallizable and the other not. Metallizable refers to the capability of being coated or impregnated with a metal. This technique does, however, have tremendous practical difficulties with its implementation. Furthermore, it is expensive, particularly regarding the construction of the molds, and the results obtained may not be entirely satisfactory in that it is difficult to obtain clear-cut boundaries where the two plastics meet. Furthermore, it offers little room for maneuvering as far as the choice of the decoration that can be produced is concerned.

Patent application FR-A-2 751 265 describes a method in which an item is formed of a metallizable material, such as an ABS (acrylonitrile butadiene styrene), a PP (polypropylene), a POM (polyoxymethylene), or a filled polyester. A sheet of a non-metallizable material such as a PVC (polyvinylchloride) or PC (polycarbonate) is over-molded on areas of the item. Again, the surface of the item on which the sheet is over-molded is not treated. The sheet merely covers that portion of the surface of the item. Next, galvanoplasty is used to deposit a metallic coating on those areas of the item which are not covered by the sheet. A method such as this is relatively complicated and expensive to implement. Furthermore, as with the technique described earlier, the possibilities regarding the decorations that can be achieved are limited.

Aside from the methods mentioned hereinabove, there are many other decorating methods which differ according to the material used. As far as plastics are concerned, mention may be made of methods involving screen printing, pad printing, ink jet printing, hot transfer, or molding. The decoration may also include a label stuck onto the item that is to be decorated.

Laser marking is a particular form of numerically-controlled marking. Laser marking is particularly advantageous particularly on account of its cleanness, the recyclability of the marked item, the permanency of the inscription, the flexibility laser marking has to offer, for example, in the choice of decoration and its customization, the resolution laser marking can achieve, and also because of how economical laser marking is to implement. Furthermore, lasers allow decoration to be done from a distance, that is to say without the item for decoration being brought into physical contact with a printing member.

Patent application FR-A-2 778 919 describes a method for using a laser to mark or etch an item formed of a polymer filled with inorganic pigments coated with a layer of chitin or chitin derivatives. A method such as this has a certain number of restrictions, particularly regarding the color and appearance that can be achieved for the decoration.

According to one aspect of the invention, a method for producing a decorative pattern on an item formed from a support made of a thermoplastic may include metallizing all or part of the support by galvanoplasty to form a metallic coating delimiting the decorative pattern. The thermoplastic surface corresponding to the decorative pattern may undergo a prior treatment so as not to be metallizable by galvanoplasty. The prior treatment may include irradiating the thermoplastic surface of the support corresponding to the decorative pattern using a laser beam.

Galvanoplasty is a technique for metallizing (i.e., coating or impregnating with metal) an object using the conductivity properties of the material of which the object is formed. The thermoplastics used may be made conductive by a multi-stage method during which the object to be galvanized is dipped in a series of baths.

In a first stage, known as “satining,” tiny roughnesses may be created on the surface of the object so as to generate anchoring points for the metal deposit. To do that, organic bridges in the structure of the object may be broken down during this stage. In the case of materials containing butadiene, such as ABS, the micro-spheres of butadiene lying at the surface of the material may be destroyed, thus giving way to micro-cavities intended to form such anchoring points.

In a second stage known as “catalysis,” stable colloidal palladium may be incorporated into the micro-cavities.

In a third stage known as “acceleration,” the protective colloid may be removed so as to activate the palladium.

In a fourth stage, the object may be rendered conductive by an operation known as “chemi-nickel plating.”

Thereafter, electrolysis may be used to deposit one or more layers of metal on the layer of nickel. In one embodiment, a layer of copper may be deposited, onto which a layer of nickel, bronze, chromium, or gold may be deposited. The layer of copper may provide the function of strengthening and improving the rigidity of the thin nickel deposit.

According to one example of the invention, prior irradiation of the surface, corresponding to the decorative pattern, with a laser beam, may inhibit the ability of the surface to be metallized by galvanoplasty. The irradiation may burn the surface of the material so that, in the satining stage of the galvanoplasty method, anchoring points capable of allowing the metal deposit to form are not created. Thus, upon leaving the various galvanoplasty baths, the part may be covered with a metal deposit on its entire surface except for the surface corresponding to the decorative pattern, to which the metal is unable to attach.

The decorative pattern may include wording, a brand mark, a logo, a design, or any other pattern. In one embodiment of an item formed according to the invention, the metallic surface delimiting the decorative pattern, in combination with the non-metallic surface formed by the decorative pattern that has undergone a laser treatment, offers aesthetic properties. Many contrast and color combinations may be possible simply by altering the choice of metallic coating or the choice of material of the support. Altering the material of the support may result in different reactivity to laser irradiation. Various contrast and color combinations might also be obtained by choosing the irradiation characteristics.

According to one embodiment of the invention, marking is quick. The cycle time, depending on the decoration and on the object, may be of the order of a few seconds. Also, the resolution of the image produced may be of good quality, on the order of a few μm. Furthermore, it may be possible to decorate surfaces of non-planar profile and those that are otherwise difficult to access using conventional screen printing or labelling techniques. The item to be decorated may be marked from a distance and without direct contact. Such a technique of decorating by laser in combination with selective galvanoplasty can be implemented in industrial installations turning out parts using equipment such as conveyors, robot arms, turntables, or any other means commonly used in industrial circles.

When being irradiated with the laser beam, the item to be decorated may be stationary, and the laser beam may be moved around according to the decoration to be produced. Alternatively, the laser beam may be stationary and the item moved around according to the decorative pattern to be produced.

In one embodiment, the laser beam may be produced by a laser of the CO₂ or YAG type, or by an excimer laser.

The support may be made of a thermoplastic such as ABS (acrylonitrile butadiene styrene), PP (polypropylene), POM (polyoxymethylene), polyamide or a polyester, each of these optionally being filled. Any other material that can be metallized by galvanoplasty may be used. The materials may be filled with any kind of filler capable, for example, of modifying their physicochemical properties.

The metallic coating delimiting the decorative pattern may be formed of a superposition of at least two layers of metals or alloys chosen, for example, from chromium, nickel, silver, gold, zinc, bronze, and copper. For example, use may be made of a superposition of a layer each of nickel, copper, and chromium.

According to one alternative embodiment, the material that can be metallized by galvanoplasty may be filled with one or more pigments so as to improve the reactivity to the laser beam of the material forming the support. Such a characteristic may make it possible, when producing the support, to use materials that do not react or do not react very much to laser irradiation. However, the filler may make it possible to modify the color and/or the appearance of the material subjected to such irradiation. The great many colors and contrasts that can be obtained according to the invention may thus be increased.

The material may be filled with pigments, for example, inorganic pigments, possibly coated with a layer of chitin or chitin derivatives. For example, the pigments may be chosen from metal oxides, such as oxides of zinc (ZnO), nanotitaniums, oxides of titanium (TiO₂), oxides of antimony (Sb₂O₃) and mica titaniums, and calcium carbonates (CaCO₃).

According to another aspect of the invention, there is also produced an item decorated by the method. For example, the item may be a container such as a case, a bottle, or a jar, an accessory associated with such a container, for example, a stopper, or both a container and an accessory.

In one embodiment, the item may form a stopper for a container intended, for example, to package a cosmetic product. The stopper may be formed of a lateral skirt, such as a cylindrical skirt. One end of the skirt may extend from a transverse wall. The decorative pattern may be formed on the transverse wall and/or on the lateral skirt.

According to one aspect of the invention, a method for producing at least one decorative pattern on an item may include providing a support having at least one surface and treating a first portion of the surface of the support. The treatment may render the first portion of the surface resistant to metallic coating by at least one type of metallic coating procedure. In addition, the method may include coating a second portion of the surface of the support with a metallic coating such that the metallic coating delimits a decorative pattern. The first portion of the surface corresponds to the decorative pattern.

According to another aspect of the invention, an item may be produced having at least one decorative pattern thereon. The item may comprise at least a portion of a container. Alternatively, the item may comprise a container and an accessory for the container. According to yet another alternative embodiment, the item may simply comprise the container.

According to another aspect of the invention, a system includes an item to be decorated and a cosmetic product contained in the item. In one exemplary embodiment, the cosmetic product comprises a scent.

It is to be understood that both the foregoing description and the following description are exemplary and explanatory only and are not restrictive of the invention, as claimed.

The accompanying drawings, which are incorporated in and constitute a part of this specification, illustrate several embodiments of the invention and together with the description, serve to explain the principles of the invention. In the drawings,

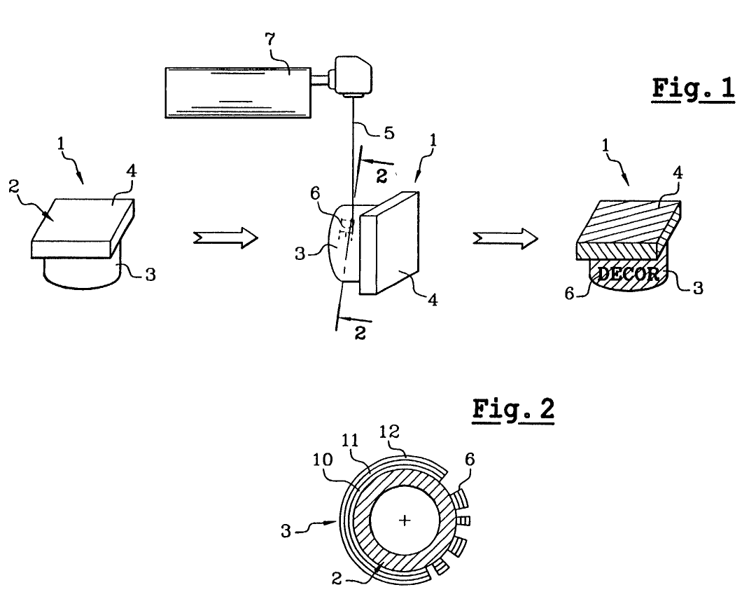

FIG. 1 is a schematic illustration of one embodiment of the method according to the invention,

FIG. 2 is a cross-section along line 2-2 of FIG. 1,

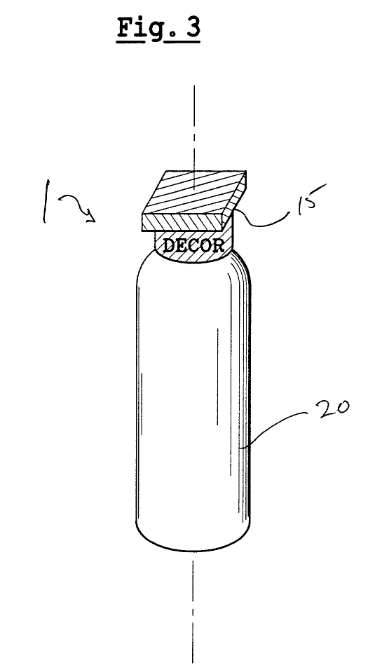

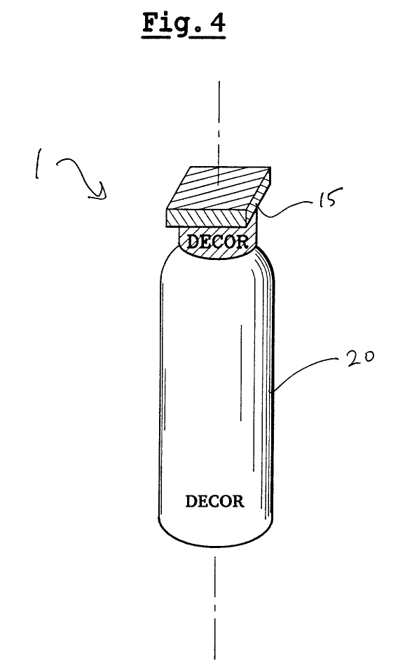

FIG. 3 is a one embodiment of a product in accordance with the invention,

FIG. 4 is an alternative embodiment of a product in accordance with the invention, and

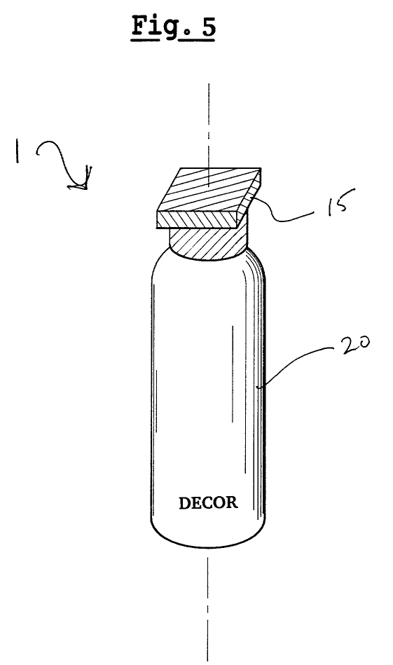

FIG. 5 is another alternative embodiment of a product in accordance with the invention.

Reference will now be made in detail to embodiments of the invention, examples of which are illustrated in the accompanying drawings. Wherever possible, the same reference numbers will be used throughout the drawings to refer to the same or like parts.

In accordance with the present invention, an item to be decorated is provided. Referring to FIG. 1, the item 1 to be decorated may be a stopper configured to fit on a container. The container may be configured as, for example, a case, a bottle, or a jar. The item 1 may be formed from a support 2, obtained by molding a galvanizable thermoplastic, such as ABS. The support 2 may comprise a cylindrical lateral skirt 3 of circular cross-section intended to engage with the neck of the container. One end of the lateral skirt 3 may extend from a transverse wall 4 of square cross-section, larger than the cross-section of the cylindrical lateral skirt 3.

A surface portion 6 of the support 2 corresponds to the decorative pattern to be produced. This portion 6 may be irradiated with a beam 5 generated by a laser 7, as shown in FIG. 1. According to one embodiment, the laser 7 may be a YAG-type laser. For example, the wavelength of the laser beam 5 may be about 1064 nm and its power may be about 9 W. In one embodiment, the surface to be decorated may be located a distance of about 200 mm away from the laser, and the focal length may be about 160 mm.

The decoration may be fairly visible on the surface of the support. Its color and its contrast may vary according to the reactivity to laser irradiation of the material of which the support is made. The reactivity of the material to the laser beam can be improved by adding pigments or fillers to the material of which the support is made.

The support 2 thus treated may then be passed through a series of baths so that its unirradiated surface can be covered, by galvanoplasty, with a coating comprising one or more metallic layers, so as to give the item 1 and the decoration 6 their final appearance.

As can be seen in the cross-sectional view of the item 1, depicted in FIG. 2, the metallic coating may be formed of a superposition of a layer 10 of nickel, a layer 11 of copper, and a layer 12 of chromium. The thickness of the three layers of metal Ni/Cu/Cr thus deposited may range from about 10 μm to about 30 μm. The surface of the support 2 corresponding to the decorative pattern 6 may be, for its part, free of any metallic deposit. According to the embodiment that has just been described, the surface corresponding to the decorative pattern 6 may be both matt and relatively dark. The metallic coating surrounding it may be of a silvery color, thus providing sufficient contrast.

As shown in FIGS. 3-5, the item 1 to be decorated may be a container or an accessory for use with a container. Referring to FIG. 3, the item 1 to be decorated may be a stopper 15 configured to fit on a container 20. As shown in FIG. 4, the item 1 to be decorated may be both the stopper 15 and the container 20 on which the stopper 15 is placed. Further, as illustrated in FIG. 5, the item 1 to be decorated may be the container 20.

In one example, the aesthetic appearance of the decorations obtained by implementing the method according to the present invention is entirely compatible with the requirements of the market for goods known as “luxury goods,” such as perfume or other cosmetic products of the same kind.

It will be apparent to those skilled in the art that various modifications and variations can be made to the decorating method and item decorated. Other embodiments of the invention will be apparent to those skilled in the art. It is intended that the specification and examples be considered as exemplary only.

What is claimed is:

1. A method for producing at least one decorative pattern on an item, comprising:
providing a support having at least one surface;
treating a first portion of the surface of the support to render the first portion of the surface resistant to metallic coating by at least one type of metallic coating procedure; and
coating a second portion of the surface of the support with a metallic coating such that the metallic coating delimits a decorative pattern, the first portion of the surface corresponding to the decorative pattern.

2. The method of claim 1, wherein said treating comprises irradiating the first portion of the surface.

3. The method of claim 2, wherein the irradiating includes using a laser beam.

4. The method of claim 1, wherein the support includes a transverse wall and a cylindrical skirt.

5. The method of claim 4, wherein the treating comprises treating the cylindrical skirt.

6. The method of claim 1, wherein the treating renders the first portion resistant to metallic coating by galvanoplasty, and wherein said coating the second portion comprises performing galvanoplasty.

7. The method of claim 1, wherein the support is formed of a thermoplastic material.

8. The method of claim 7, wherein the thermoplastic material is chosen from ABS (acrylonitrile butadiene styrene), PP (polypropylene), POM (polyoxymethylene), polyamide, and polyester.

9. The method of claim 8, wherein the thermoplastic material is filled.

10. The method of claim 1, wherein the metallic coating comprises a superposition of at least two layers of metals comprising at least one of chromium, nickel, silver, gold, zinc, bronze, and copper.

11. The method of claim 1, wherein the metallic layer comprises a superposition of at least two layers of alloys comprising at least one of chromium, nickel, silver, gold, zinc, bronze, and copper.

12. The method of claim 3, wherein at least the first portion of the support includes a substance for improving reactivity of the first portion.

13. The method of claim 12, wherein the substance comprises at least one pigment in material forming at least the first portion of the support.

14. The method of claim 13, wherein the at least one pigment comprises inorganic pigment.

15. The method of claim 13, wherein the at least one pigment is coated with a layer comprising a material chosen from chitin and chitin derivatives.

16. The method of claim 13, wherein the at least one pigment comprises metal oxide.

17. The method of claim 16, wherein the at least one metal oxide is chosen from oxides of zinc (ZnO), nanotitaniums, oxides of titanium (TiO₂), oxides of antimony (Sb₂O₃), and mica titaniums.

18. The method of claim 3, further comprising emitting the laser beam from a laser chosen from a CO₂-type laser a YAG-type laser, and an excimer laser.

19. The method of claim 1, wherein the item is configured in the form of a container.

20. The method of claim 1, wherein the item is configured in the form of an accessory intended to be associated with a container.

21. The method of claim 20, wherein the item is configured in the form of a stopper.

22. The method of claim 21, wherein the item comprises a lateral wall and a cylindrical skirt, the decorative pattern being formed on one of the lateral wall support and the skirt.

23. An item produced by the process of claim 1.

24. The item of claim 23, wherein the item comprises at least a portion of a container.

25. The item of claim 23, wherein the item is configured in the form of an accessory intended to be associated with a container.

26. The item of claim 25, wherein the item is configured in the form of a stopper configured to close a container.

27. The item of claim 25, comprising a lateral wall and a cylindrical skirt, the decorative pattern being formed on one of the lateral wall and the skirt.

28. A system comprising:
the item of claim 24; and
a cosmetic product contained in the item.

29. The system of claim 28, wherein the cosmetic product comprises a scent.

30. A system comprising:
a container containing a cosmetic product; and
the item of claim 26 on the container.

31. The system of claim 30, wherein the cosmetic product comprises a scent.

32. The method of claim 1, wherein said coating the second portion includes metallizing the second portion.

33. The method of claim 32, wherein said metallizing the second portion comprises performing galvanoplasty on at least the second portion.

34. The method of claim 32, wherein said metallizing the second portion comprises performing galvanoplasty on at least the first portion and the second portion.

35. A method for producing a decorative pattern on an item, comprising:
providing a support having at least one surface;
treating a portion of the surface of the support such that the treated portion is resistant to at least one type of metallizing, the treated portion corresponding to a decorative pattern; and
metallizing at least part of the support to form a metallic coating delimiting the decorative pattern.

36. The method of claim 35, wherein said treating comprises irradiating the first portion of the surface.

37. The method of claim 36, wherein the irradiating includes using a laser beam.

38. The method of claim 35, wherein the treating renders the first portion resistant to metallic coating by galvanoplasty, and wherein said metallizing comprises performing galvanoplasty.

39. The method of claim 35, wherein the support is formed of a thermoplastic material.
